(19) United States
(12) Patent Application Publication
(10) Pub. No.: US 2008/0183407 A1
(43) Pub. Date: Jul. 31, 2008

(54) SYSTEM AND METHOD FOR TESTING POWER INTENSIFY OF RFID TAGS

(75) Inventors: Hsin-Hsien Yeh, Taichung City (TW); Ying-Chang Hung, Hsinchu Hsien (TW); Hong-Ching Lin, Kaohsiung City (TW)

Correspondence Address: WPAT, PC;INTELLECTUAL PROPERTY ATTORNEYS, 2030 MAIN STREET, SUITE 1300, IRVINE, CA, 92614, US

(73) Assignee: INDUSTRIAL TECHNOLOGY RESEARCH INSTITUTE, Hsinchu Hsien (TW)

(21) Appl. No.: 11/964,647

(22) Filed: Dec. 26, 2007

(30) Foreign Application Priority Data
Dec. 27, 2006 (TW) 095149151

(51) Int. Cl. G01R 21/06; G01R 31/00; H04Q 5/22; G01N 37/00; G08B 13/14

(52) U.S. Cl. 702/60; 324/500; 340/572.1; 340/10.1; 702/81

(57) ABSTRACT

The invention provides a system and method for testing the power intensity of RFID tags. The method is applicable to the system for testing power intensity, which comprises a RFID reading device, a signal transmitting device electrically coupled to the RFID reading device, a signal separating device electrically coupled to the signal transmitting device and a control analysis device electrically coupled to the signal separating device. The system is applicable to a RFID tag or a test object attached with a RFID tag in a non-shielded or shielded room.

### FIELD OF THE INVENTION

The present invention relates to a system and method for testing the power intensity of RFID tags, and more particularly, to a method and system for testing the power intensity of RFID tags applicable to a power intensity testing system, which is applicable to a RFID tag or a test object attached with a RFID tag in a non-shielded or shielded room.

### BACKGROUND OF THE INVENTION

Along with the advancement in electronic technology, present RFID technology has achieved several breakthrough, for example, manual reading of the bar codes is no longer required; several tags can be read simultaneously and under severe environment and from long distance; real-time tracking and high speed reading are possible; and RFID tags are re-readable and rewritable.

RFID technology has been widely used in various fields, such as in entry control, cattle management, and logistic management etc. Thus, design of RFID tags has to change according to the applied environment to achieve the optimal performance. In order to meet the requirement of actual applications, the characteristics of RFID tags has to be evaluated quickly. Currently, RFID testing involves a reader (including antenna) and test objects (i.e. RFID tags) attached to different items. The reader tests to see if signals from the RFID tags are read to identify their performance. However, the signals are transmitted via electromagnetic waves, the strength of which may be deteriorated by metal and moisture content. This would affect the signals feedback by the RFID tags. This method of testing cannot reliably test the optimal power intensity of the RFID tags.

In TW patent No. 330297 titled “Method for classifying non-contact RFID elements and Device thereof”, an automatic classifying device is proposed. A RFID element is placed inside the classifying device for automatic testing by transmitting a signal to the RFID element from a reader, reading a signal feedback from the RFID element by the reader, and determining whether the feedback signal received by the reader passes a test or not and performing classification accordingly by a computer. However, this device tests whether the RFID signal is good or bad, it does not test the optimal power intensity of the RFID tags.

TW patent publication No. 200634640 titled “RFID Testing System” describes a mechanism of a RFID testing system and how the mechanism is moved and controlled; it also fails to mention how to test the optimal power intensity of the RFID tags.

U.S. Pat. No. 598333 titled “In-Sheet Transceiver Testing” describes a method for a test fixture system to test the sensitivity of a RFID tag. A reader on the test fixture first transmits a signal. Upon receiving the signal, the RFID tag feedback the signal to the reader to be analyzed for signal strength by the reader, wherein the transmission and reception of the reader is controlled by a RF switch. In this case, the feedback signal is not transmitted to a more specialized instrument for signal strength analysis and statistics, but rather to reader itself for signal strength analysis. Thus, the sensitivity of signal analysis cannot be enhanced. Moreover, the above three prior arts can be applied to a shielded room only.

Therefore, there is a strong need for a method and system for testing the optimal power intensity of a RFID tag, not only in the shielded room, but also in a non-shielded room.

### SUMMARY OF THE INVENTION

In the light of forgoing drawbacks, an objective of the present invention is to provide a method and system for accurately testing the power intensity of RFID tags.

In accordance with the above and other objectives, the present invention provides a method for testing the power intensity of RFID tags applicable a power intensity testing system, which is applicable to a RFID tag or a test object attached with a RFID tag, the method comprising the steps of:

outputting a plurality of signals to the signal transmitting device by a RFID reading device, wherein the signal transmitting device is electrically coupled to the RFID reading device;

transmitting, by the signal transmitting device, the plurality of signals to the RFID tag of the test object and receiving and sending, by the signal transmitting device, a plurality of tag signals feedback by the test object to a signal separating device, wherein the signal separating device is electrically coupled to the signal transmitting device;

separating each of the tag signals into a tag information signal and a tag intensity signal and transmitting the tag intensity signal to a control analysis device by the signal separating device, wherein the control analysis device is electrically coupled to the signal separating device;

performing a filtering process on each tag intensity signal by the control analysis device to obtain a response interval waveform of each tag intensity signal; and

analyzing and gathering statistics of the response interval waveform of each tag intensity signal by the control analysis device to obtain and output the power intensity of the RFID tag.

In accordance with the above and other objectives, the present invention provides a system for testing the power intensity of RFID tags, comprising: a RFID reading device for outputting a plurality of signals; a signal transmitting device electrically coupled to the RFID reading device for transmitting the plurality of signals to a RFID tag of a test object and receiving a plurality of tag signals feedback by the test object; a signal separating device electrically coupled to the signal transmitting device for separating each of the tag signals into a tag information signal and a tag intensity signal; and a control analysis device electrically coupled to the signal separating device for performing a filtering process on each tag intensity signal to obtain a response interval waveform of each tag intensity signal and analyzing and gathering statistics of the response interval waveform of each tag intensity signal to obtain and output the power intensity of the RFID tag.

The abovementioned control analysis device may control the five-axial variations of the signal transmitting device and the three-axial variations of the test object automatically or manually.

The abovementioned signal transmitting device is an antenna and the signal separating device is one of an isolator, a coupler and a circulator.

The abovementioned signal transmitting device is electrically coupled to the signal separating device. The system further comprises a signal amplifying device for amplifying the plurality of feedback tag signals received by the signal transmitting signal and transmitting the plurality of amplified feedback tag signals to the signal separating device, wherein the signal amplifying device is a signal amplifier.

The abovementioned control analysis device performs sampling and pre-processing based on frequency or phase parameters to extract an intensity signal waveform of each tag intensity signal before performing the filtering process on each tag intensity signal.

The abovementioned control analysis device further comprises: a filtering unit for performing the filtering process on the tag intensity signal; an analysis unit for obtaining a maximum value of the response interval waveform; and a statistic unit for gathering statistics of the response interval waveform to obtain an average value of the power intensity.

The abovementioned filtering unit performs filtering by one of a firmware and a hardware, where the firmware includes a firmware filtering process and the hardware includes a filter.

The abovementioned analysis unit performs analysis by one of a firmware and a hardware, wherein the firmware includes a firmware spectrum analysis process and the hardware includes a spectrum analyzer.

The abovementioned shielded room is a noise-absorbing test environment and the non-shielded room is a normal test environment.

The test object includes one of an active RFID tag and a passive RFID tag.

The outputting of the power intensity of the RFID tag includes displaying the power intensity of the RFID tag in a 2-D or 3-D diagram on a monitor or printing on a printout.

Compared to prior art, the method and system for testing the power intensity of RFID tags of the present invention first electrically connects the RFID reading device, the control analysis device, the signal transmitting device, the signal amplifying device and the signal separating device. The signal transmitting device transmits a plurality of signals to the test object for testing. The test object receives the signals and feedback a plurality of tag signals to the signal transmitting device. The signal transmitting device then sends the tag signals to a signal amplifying device. The signal amplifying device amplifies the tag signals and sends them to the signal separating device, which then separates each of the tag signals into a tag information signal and a tag intensity signal. Thereafter, the tag intensity signal is transmitted to the control analysis device for filtering to obtain a response interval waveform. Then, an analysis unit of the control analysis device obtains the maximum value of the response interval waveform, and a statistic unit of the control analysis device obtains the average value of the power intensity of the RFID tag, thereby achieving the purpose of testing the optimum power intensity of RFID tags.

### BRIEF DESCRIPTION OF THE DRAWINGS

The present invention can be more fully understood by reading the following detailed description of the preferred embodiments, with reference made to the accompanying drawings, wherein:

FIG. 1 is a flowchart depicting the steps of a method for testing power intensity of RFID tags; and

FIG. 2 is a block diagram depicting a system for testing power intensity of RFID tags.

### DETAILED DESCRIPTION OF THE EMBODIMENTS

The present invention is described by the following specific embodiments. Those with ordinary skills in the arts can readily understand the other advantages and functions of the present invention after reading the disclosure of this specification. The present invention can also be implemented with different embodiments. Various details described in this specification can be modified based on different viewpoints and applications without departing from the scope of the present invention.

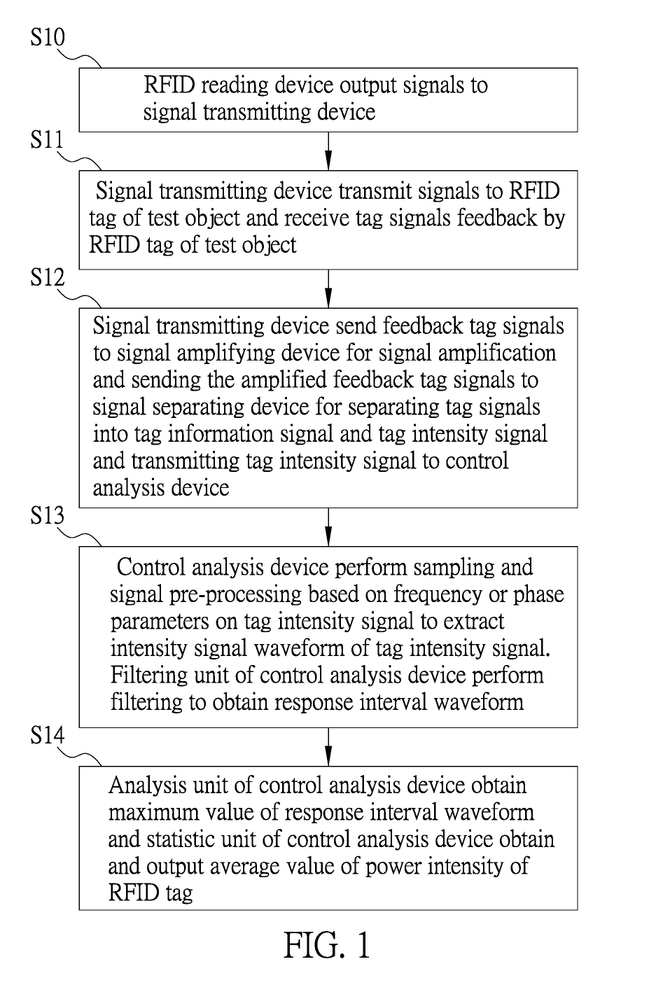

FIG. 1 is a flowchart depicting the steps of a method for testing power intensity of RFID tags. The method is applied to a power intensity testing system, which is applicable to a RFID tag or a test object attached with a RFID tag.

The method for testing power intensity of a RFID tag first performs step S10, where a RFID reading device outputs a plurality of signal to a signal transmitting device, wherein the signal transmitting device is electrically coupled to the RFID reading device, then step S11 is performed.

In step S11, the signal transmitting device transmits the plurality of tag reading signals to the RFID tag of the test object and receives a plurality of tag signals feedback by the RFID tag of the test object.

In step S12, the signal transmitting device sends the feedback tag signals to a signal amplifying device for signal amplification. Thereafter, the amplified feedback tag signals are transmitted to a signal separating device, which is electrically coupled to the signal transmitting device and separates each of the tag signals into a tag information signal and a tag intensity signal. Each tag intensity signal is transmitted to a control analysis device, wherein the control analysis device is electrically coupled to the signal separating device. Then, step S13 is performed.

In step S13, the control analysis device performs sampling and signal pre-processing based on frequency or phase parameters, so as to extract an intensity signal waveform of the tag intensity signal. Then, a filtering unit of the control analysis device performs filtering on the waveform to obtain a response interval waveform. Then, step S14 is performed.

In step S14, an analysis unit of the control analysis device obtains a maximum value of the response interval waveform and a statistic unit of the control analysis device obtains the average value of the power intensity of the RFID tag and outputs the average. In this embodiment, the output includes displaying the power intensity of the RFID tag in 2-D or 3-D on a monitor.

The principles and effects of the present invention are discussed in more details below. The method for testing the power intensity of RFID tags in this embodiment performs testing under a normal or a noise-absorbing test environment by using an automatic setup procedure. First, the RFID reading device, the control analysis device, the signal transmitting device, the signal amplifying device and the signal separating device are electrically coupled, for example, via transmission lines. The signal transmitting device is an antenna. The signal amplifying device is a signal amplifier. The signal separating device is a coupler. The test object is a passive RFID tag. The method for testing the power intensity of a RFID tag allows the RFID reading device to setup and send a plurality of signals to the antenna. The antenna transmits the signals to the passive RFID tag, which can be adhered to a metal or non-metal item. A simulation test is performed for 1000 times, for example. The number of tests can be varied as desired. In addition, the five-axial variations (i.e. X-axial, Y-axial, Z-axial, horizontal angle and vertical angle) of the antenna and the three-axial variations (i.e. X-axial, Y-axial and rotational axial) of the passive RFID tag are controlled by the control analysis device.

After receiving the plurality of signals, the RFID tag feedback a plurality of tag signals to the antenna. The antenna sends the feedback tag signals to the signal amplifier for signal amplification. Thereafter, the signal amplifier sends the amplified feedback tag signals to the coupler for signal separation. The coupler separates each of the tag signals into a tag information signal and a tag intensity signal and transmits each tag intensity signal to the control analysis device. The control analysis device performs sampling and signal pre-processing based on frequency or phase parameters, so as to extract an intensity signal waveform of the tag intensity signal. Then, the filtering unit (i.e. a firmware filtering process) of the control analysis device performs filtering on the waveform to obtain a response interval waveform. Thereafter, an analysis unit (i.e. spectrum analyzer) of the control analysis device obtains a maximum value of the response interval waveform and a statistic unit of the control analysis device obtains the average value of the power intensity of the RFID tag and outputs the average value in 2-D or 3-D on a monitor.

In another embodiment, which is similar to the previous embodiment, the difference is that the user may choose to perform testing under a normal or a noise-absorbing test environment by using a manual setup procedure. The manual setup procedure depends on the desired test items, wherein the RFID tag of the test object is changed to an active RFID tag. The signal separating device is changed to one of an isolator and a circulator. The filtering unit performs signal filter via hardware (i.e. a filter). The analysis unit performs signal analysis via firmware (i.e. a firmware spectrum analysis process). The average of the power intensity of the RFID tag can also be outputted onto a printout in a 2-D or 3-D diagram.

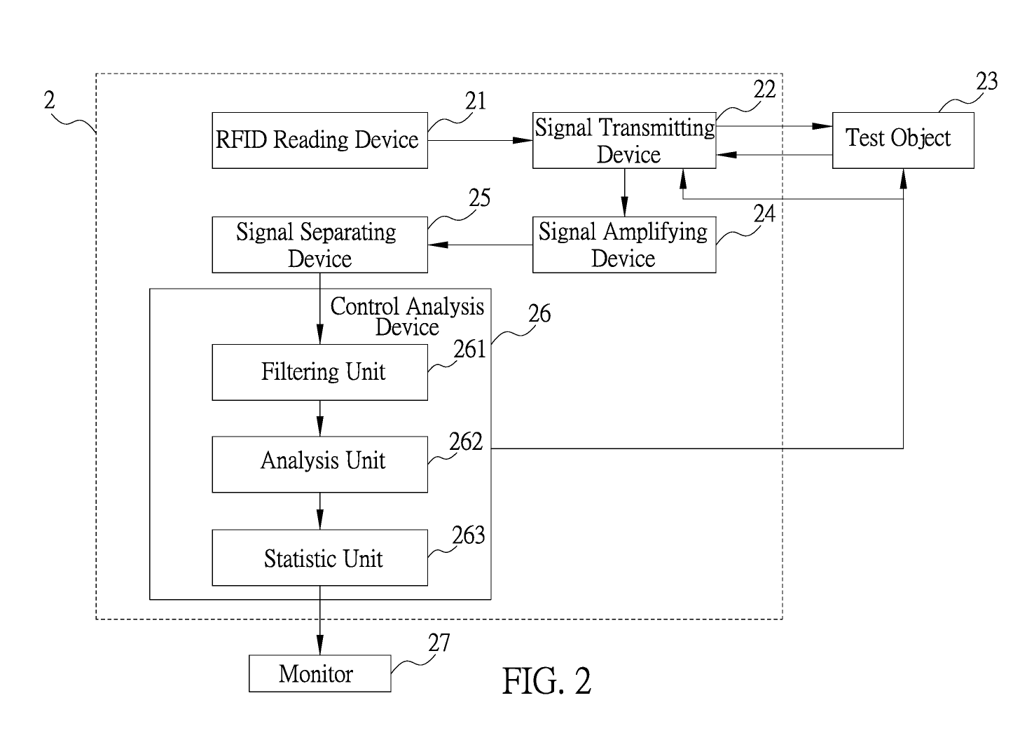

FIG. 2 is a block diagram depicting a system for testing power intensity of RFID tags.

The system for testing power intensity of RFID tags 2 includes: a RFID reading device 21 for outputting a plurality of signals to a signal transmitting device 22. The signal transmitting device 22 transmits the plurality of signals to a RFID tag of a test object 23 and receives and sends a plurality of tag signals feedback by the test object 23 to a signal amplifying device 24 for signal amplification. Thereafter, the amplified feedback tag signals are transmitted to a signal separating device 25, which separates each of the tag signals into a tag information signal and a tag intensity signal. The tag intensity signal is then transmitted to the control analysis device 26. A filtering unit 261 of a control analysis device 26 performs filtering on each tag intensity signal to obtain a response interval waveform of each tag intensity signal. Then, an analysis unit 262 of the control analysis device 26 analyses the response interval waveform of each tag intensity signal and a statistic unit 263 of the control analysis device 26 obtains the average value of the power intensity of the RFID tag and outputs the result in a 2-D or 3-D diagram on a monitor 27 or on a printout.

In summary, the method and system for testing the power intensity of a RFID tag performs power intensity test on various RFID tags, changes the five-axial variations (i.e. X-axial, Y-axial, Z-axial, horizontal angle and vertical angle) of transmission and reception of the antenna and the three-axial variations (i.e. X-axial, Y-axial and rotational axial) of the RFID tag and gathers statistical data of the tested power intensity in order to obtain the optimal power intensity of the various RFID tags .

The above embodiments are only used to illustrate the principles of the present invention, and they should not be construed as to limit the present invention in any way. The above embodiments can be modified by those with ordinary skills in the arts without departing from the scope of the present invention as defined in the following appended claims.

What is claimed is:

1. A method for testing the power intensity of RFID tags applicable to a power intensity testing system, which is applicable to a RFID tag or a test object attached with a RFID tag, the method comprising the steps of:
outputting a plurality of signals to a signal transmitting device by a RFID reading device, wherein the signal transmitting device is electrically coupled to the RFID reading device;
transmitting, by the signal transmitting device, the plurality of signals to the RFID tag of the test object and receiving and sending, by the signal transmitting device, a plurality of tag signals feedback by the test object to a signal separating device, wherein the signal separating device is electrically coupled to the signal transmitting device;
separating each of the tag signals into a tag information signal and a tag intensity signal and transmitting the tag intensity signal to a control analysis device by the signal separating device, wherein the control analysis device is electrically coupled to the signal separating device;
performing a filtering process on each tag intensity signal by the control analysis device to obtain a response interval waveform of each tag intensity signal; and
analyzing and gathering statistics of the response interval waveform of each tag intensity signal by the control analysis device to obtain and output the power intensity of the RFID tag.

2. The method for testing the power intensity of RFID tags of claim 1, wherein the control analysis device controls the five-axial variations of the signal transmitting device and the three-axial variations of the test object automatically or manually.

3. The method for testing the power intensity of RFID tags of claim 1, wherein the signal transmitting device is an antenna.

4. The method for testing the power intensity of RFID tags of claim 1, wherein the signal separating device is one of an isolator, a coupler and a circulator.

5. The method for testing the power intensity of RFID tags of claim 1, wherein the signal transmitting device is electrically coupled to the signal separating device, further comprising a signal amplifying device for amplifying the plurality of feedback tag signals received by the signal transmitting signal and transmitting the plurality of amplified feedback tag signals to the signal separating device.

6. The method for testing the power intensity of RFID tags of claim 5, wherein the signal amplifying device is a signal amplifier.

7. The method for testing the power intensity of RFID tags of claim 1, wherein before performing the filtering process on each tag intensity signal by the control analysis device, performing sampling and pre-processing based on frequency or phase parameters to extract an intensity signal waveform of each tag intensity signal.

8. The method for testing the power intensity of RFID tags of claim 1, wherein the control analysis device further comprises:
a filtering unit for performing the filtering process on the tag intensity signal;
an analysis unit for obtaining a maximum value of the response interval waveform; and
a statistic unit for gathering statistics of the response interval waveform to obtain an average value of the power intensity.

9. The method for testing the power intensity of RFID tags of claim 8, wherein the filtering unit performs filtering by a firmware.

10. The method for testing the power intensity of RFID tags of claim 9, wherein the firmware includes a firmware filtering process.

11. The method for testing the power intensity of RFID tags of claim 8, wherein the filtering unit performs filtering by a hardware.

12. The method for testing the power intensity of RFID tags of claim 11, wherein the hardware includes a filter.

13. The method for testing the power intensity of RFID tags of claim 8, wherein the analysis unit performs analysis by a firmware.

14. The method for testing the power intensity of RFID tags of claim 13, wherein the firmware includes a firmware spectrum analysis process.

15. The method for testing the power intensity of RFID tags of claim 8, wherein the analysis unit performs analysis by a hardware.

16. The method for testing the power intensity of RFID tags of claim 15, wherein the hardware includes a spectrum analyzer.

17. The method for testing the power intensity of RFID tags of claim 1, wherein the test object includes an active RFID tag.

18. The method for testing the power intensity of RFID tags of claim 1, wherein the test object includes a passive RFID tag.

19. The method for testing the power intensity of RFID tags of claim 1, wherein the outputting of the power intensity of the RFID tag includes displaying the power intensity of the RFID tag in a 2-D or 3-D diagram on a monitor.

20. The method for testing the power intensity of RFID tags of claim 1, wherein the outputting of the power intensity of the RFID tag includes printing the power intensity of the RFID tag in a 2-D or 3-D diagram on a printout.

21. A system for testing the power intensity of RFID tags applicable to a power intensity testing system, which is applicable to a RFID tag or a test object attached with a RFID tag, comprising:
a RFID reading device for outputting a plurality of signals;
a signal transmitting device electrically coupled to the RFID reading device for transmitting the plurality of signals to the RFID tag of the test object and receiving a plurality of tag signals feedback by the test object;
a signal separating device electrically coupled to the signal transmitting device for separating each of the tag signals into a tag information signal and a tag intensity signal; and
a control analysis device electrically coupled to the signal separating device for performing a filtering process on each tag intensity signal to obtain a response interval waveform of each tag intensity signal and analyzing and gathering statistics of the response interval waveform of each tag intensity signal to obtain and output the power intensity of the RFID tag.

22. The system for testing the power intensity of RFID tags of claim 23, wherein the control analysis device controls the five-axial variations of the signal transmitting device and the three-axial variations of the test object automatically or manually.

23. The system for testing the power intensity of RFID tags of claim 23, wherein the signal transmitting device is an antenna.

24. The system for testing the power intensity of RFID tags of claim 23, wherein the signal separating device is one of an isolator, a coupler and a circulator.

25. The system for testing the power intensity of RFID tags of claim 23, wherein the signal transmitting device is electrically coupled to the signal separating device, further comprising a signal amplifying device for amplifying the plurality of feedback tag signals received by the signal transmitting signal and transmitting the plurality of amplified feedback tag signals to the signal separating device.

26. The system for testing the power intensity of RFID tags of claim 27, wherein the signal amplifying device is a signal amplifier.

27. The system for testing the power intensity of RFID tags of claim 23, wherein the control analysis device performs sampling and pre-processing based on frequency or phase parameters to extract an intensity signal waveform of each tag intensity signal before performing the filtering process on each tag intensity signal.

28. The system for testing the power intensity of RFID tags of claim 23, wherein the control analysis device further comprises:
a filtering unit for performing a filtering process on the tag intensity signal;
an analysis unit for obtaining a maximum value of the response interval waveform; and
a statistic unit for gathering statistics of the response interval waveform to obtain an average value of the power intensity.

29. The system for testing the power intensity of RFID tags of claim 30, wherein the filtering unit performs filtering by a firmware.

30. The system for testing the power intensity of RFID tags of claim 31, wherein the firmware includes a firmware filtering process.

31. The system for testing the power intensity of RFID tags of claim 30, wherein the filtering unit performs filtering by a hardware.

32. The system for testing the power intensity of RFID tags of claim 33, wherein the hardware includes a filter.

33. The system for testing the power intensity of RFID tags of claim 30, wherein the analysis unit performs analysis by a firmware.

34. The system for testing the power intensity of RFID tags of claim 35, wherein the firmware includes a firmware spectrum analysis process.

35. The system for testing the power intensity of RFID tags of claim 30, wherein the analysis unit performs analysis by a hardware.

36. The system for testing the power intensity of RFID tags of claim 37, wherein the hardware includes a spectrum analyzer.

37. The system for testing the power intensity of RFID tags of claim 23, wherein the test object includes an active RFID tag.

38. The system for testing the power intensity of RFID tags of claim 23, wherein the test object includes a passive RFID tag.

39. The system for testing the power intensity of RFID tags of claim 23, wherein the outputting of the power intensity of the RFID tag includes displaying the power intensity of the RFID tag in a 2-D or 3-D diagram on a monitor.

40. The system for testing the power intensity of RFID tags of claim 23, wherein the outputting of the power intensity of the RFID tag includes printing the power intensity of the RFID tag in a 2-D or 3-D diagram on a printout.

41-44. (canceled)
